(19) United States
(12) Patent Application Publication
(10) Pub. No.: US 2009/0072644 A1
(43) Pub. Date: Mar. 19, 2009

(54) THRUST MAGNETIC BEARING SYSTEM

(75) Inventors: Dong-Chul HAN, Gangnam-gu (KR); In-Bae Chang, Seodaemun-gu (KR); In-Hwang Park, Anyang-si (KR); Young-Ho Park, Gwanak-gu (KR)

Correspondence Address: OBLON, SPIVAK, MCCLELLAND MAIER & NEUSTADT, P.C., 1940 DUKE STREET, ALEXANDRIA, VA, 22314, US

(73) Assignee: Seoul National University Industry Foundation, Seoul (KR)

(21) Appl. No.: 11/950,656

(22) Filed: Dec. 5, 2007

(30) Foreign Application Priority Data
Sep. 14, 2007 (KR) 10-2007-0093836

(51) Int. Cl. H02K 7/09; G01B 7/14; G01R 27/26

(52) U.S. Cl. 310/90.5; 324/658

(57) ABSTRACT

A thrust magnetic bearing system separates magnetic circuits of electromagnets from those of permanent magnets so that each permanent magnet produces a bias magnetic field while each electromagnet functions only to control the position of a rotating body, thereby achieving desired displacement and current stiffness without flowing a bias current through the electromagnet. The magnetic bearing system includes a thrust displacement sensor and a thrust magnetic bearing to float a disk floating body based on displacement information detected through the displacement sensor. The magnetic bearing includes a donut permanent magnet, a pair of electromagnets connected in series to form an inductor at both sides of the donut permanent magnet, and a pair of magnetic poles provided opposite each other outside the pair of electromagnets. The magnetic bearing floats the floating body through a bias magnetic flux generated by the permanent magnet and a control magnetic flux generated by the electromagnets.

### BACKGROUND OF THE INVENTION

1. Field of the Invention

The present invention relates to a thrust magnetic bearing system, and more particularly to a thrust magnetic bearing system wherein magnetic circuits of electromagnets are separated from those of permanent magnets so that each permanent magnet produces a bias magnetic field while each electromagnet functions only to control the position of a rotating body, thereby making it possible to achieve desired displacement and current stiffness without flowing a bias current through the electromagnet.

2. Description of the Related Art

Recently, a magnetic bearing is widely used in various precision mechanical devices.

The magnetic bearing floats and supports a rotating body by a magnetic force generated by an electromagnet. Precision mechanical devices with a magnetic bearing prevent the generation of dust by abrasion of its shaft and bearing and also use no lubricant, so that they have various advantages such as low maintenance costs, a high rotation rate, and low noise.

Due to these advantages, the magnetic bearing is widely used in mechanical devices, which are employed in extremely clean environments such as clean rooms for semiconductor fabrication, and in aerospace fields in which it is difficult to use mechanical bearings since the coefficient of friction is very high in vacuum.

The magnetic bearing controls the supply of current to an electromagnet according to the position of a rotating body to generate a magnetic force, thereby floating and supporting the rotating body and controlling the movement of the floated rotating body.

FIG. 10 illustrates the concept of a conventional magnetic bearing using two electromagnets.

The magnetic bearing stably supports a floating body by increasing and decreasing a magnetic force, which each electromagnet produces, depending on changes in the position of the floating body while each pair of opposing magnetic poles of the electromagnets attract the floating body. The magnetic bearing requires a contactless displacement sensor to detect the displacement of the floating body.

That is, the magnetic bearing increases and decreases the magnetic force produced by each electromagnet by controlling current flowing through the electromagnet according to changes in the position of the floating body. The magnetic bearing must also previously apply a bias magnetic force to the floating body according to the weight of the floating body and then actively increase and decrease the bias magnetic force according to changes in the position of the floating body.

However, this conventional magnetic bearing reduces the available operation range of electromagnet drivers since it previously applies a bias magnetic force to the floating body. The magnetic bearing requires larger electromagnets to compensate for the reduction in the operating range. The magnetic bearing also requires a pair of electromagnet drivers since it uses the electromagnets while flowing current through the electromagnets in only one direction.

However, there are limitations to using the magnetic bearing in devices such as a turbo compressor for vehicles having a limited space for mounting a rotating shaft and a bearing since the size of each electromagnet and the sectional area of each pole, from which a magnetic force is produced, must be minimized so that the magnetic bearing cannot afford to supply a bias current using the electromagnet drivers.

A permanent magnet bias type magnetic bearing has been suggested to overcome the problem that the bias current limits the use of the magnetic bearing. As shown in FIG. 11, the permanent magnet bias type magnetic bearing previously produces a bias magnetic force using permanent magnets 100 and increases and decreases a control magnetic force by controlling current to flow through electromagnets in two directions, thereby supporting a rotating body.

Since it is not necessary to form a bias magnetic force, the permanent magnet bias type magnetic bearing has a wide variation range of magnetic forces produced by the electromagnets, thereby making it possible to mount the magnetic bearing even in a narrow space and to reduce the amount of generated heat as the power consumption is reduced.

However, when the permanent magnet bias type magnetic bearing increases and decreases the magnetic forces produced by the electromagnets by controlling current applied to the electromagnets, the magnetic fields produced by the electromagnets pass through the permanent magnets so that the magnetic circuits of the electromagnets interfere with those of the permanent magnets, thereby reducing displacement and current stiffness characteristics of the magnetic bearing.

### SUMMARY OF THE INVENTION

Therefore, the present invention has been made in view of the above problems, and it is an object of the present invention to provide a thrust magnetic bearing system wherein magnetic circuits of electromagnets are separated from those of permanent magnets so that each permanent magnet produces a basic magnetic field while each electromagnet functions only to control a magnetic force to control the position of a rotating body, thereby making it possible to float the rotating body without flowing a bias current through the electromagnet.

In accordance with the present invention, the above and other objects can be accomplished by the provision of a thrust magnetic bearing system including a thrust displacement sensor and a thrust magnetic bearing, the system floating a disk floating body based on displacement information detected through the thrust displacement sensor, the thrust magnetic bearing including a donut permanent magnet; a pair of electromagnets connected in series to form an inductor at both sides of the donut permanent magnet; and a pair of magnetic poles provided opposite each other outside the pair of electromagnets, wherein the thrust magnetic bearing floats the disk floating body through a bias magnetic flux generated by the donut permanent magnet and a control magnetic flux generated by the electromagnets.

Preferably, the thrust displacement sensor includes a shaft having different diameters; a pair of ring electrodes provided outside the shaft; and a guard electrode surrounding the pair of ring electrodes, wherein the thrust displacement sensor detects changes in a capacitance formed by the ring electrodes by amplifying the capacitance changes using a differential amplifier.

### BRIEF DESCRIPTION OF THE DRAWINGS

The above and other objects, features and other advantages of the present invention will be more clearly understood from the following detailed description taken in conjunction with the accompanying drawings, in which:

FIG. 1 illustrates the configuration of a thrust magnetic bearing system according to the present invention;

FIGS. 2 to 4 illustrate how the thrust magnetic bearing system of FIG. 1 operates;

FIG. 5 illustrates the configuration of a thrust displacement sensor shown in FIG. 1;

FIG. 6 illustrates a capacitance model of the thrust displacement sensor of FIG. 5;

FIG. 7 is an equivalent circuit diagram of FIG. 6;

FIGS. 8A to 8E illustrate the configuration of switches to detect a capacitance using the thrust displacement sensor of FIG. 1;

FIG. 9 illustrates a basic circuit implemented for a charge transfer method used for signal detection through the thrust displacement sensor of the invention; and

FIGS. 10 and 11 illustrate the concept of a conventional thrust magnetic bearing.

### DETAILED DESCRIPTION OF THE PREFERRED EMBODIMENTS

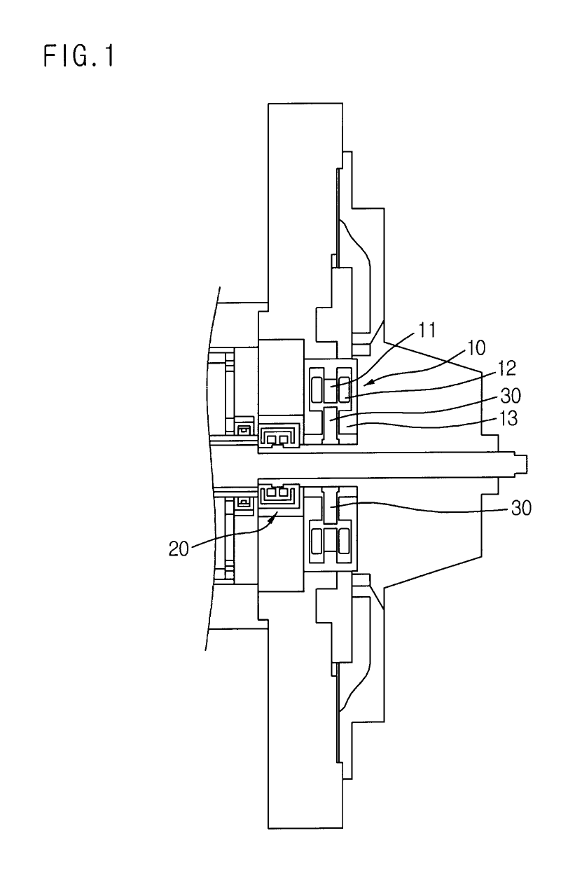

FIG. 1 illustrates the configuration of a thrust magnetic bearing system according to the present invention, which includes a thrust displacement sensor and a thrust magnetic bearing and floats a disk floating body based on displacement information detected through the thrust displacement sensor.

In FIG. 1, a thrust magnetic bearing 10 includes a donut permanent magnet 11, a pair of electromagnets 12 (specifically, a pair of coils), and a pair of magnetic poles 13 (specifically, a pair of cores). The pair of electromagnets 12 are connected in series to form an inductor at both sides of the donut permanent magnet 11. The pair of magnetic poles 13 are provided opposite each other outside the pair of electromagnets 12.

The thrust magnetic bearing 10 floats the disk floating body 30 through a bias magnetic flux (or circuit) generated by the donut permanent magnet 11 and a control magnetic flux generated by the electromagnets 12.

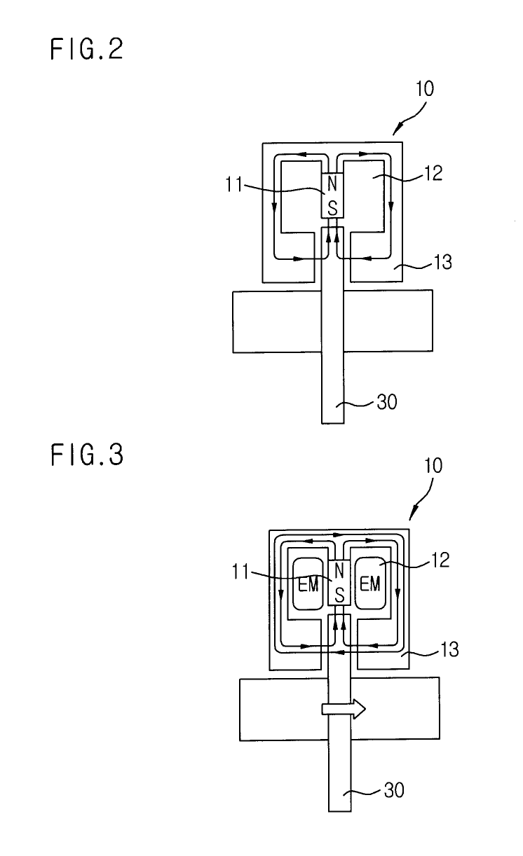

As shown in FIG. 2, the thrust magnetic bearing 10 floats the disk floating body 30 through a bias flux generated by the permanent magnet 11 even in an initial state in which no bias current is supplied to the electromagnets.

Changes in the position of the disk floating body 30 are detected through the thrust displacement sensor 20 and the disk floating body 30 is moved horizontally by controlling the direction and amount of current applied to the electromagnets 12 based on the detection.

For example, if the floating body 30 is moved to the left, the direction and amount of current applied to the electromagnets 12 is controlled to allow the electromagnets 12 to generate a control magnetic flux in a clockwise direction, thereby moving the floating body 30 to the right, as shown in FIG. 3, which illustrates only the upper side of each of the electromagnets 12.

More specifically, the bias magnetic flux generated by the permanent magnet 11 sequentially passes through a housing, gaps, and the disk floating body 30 and then returns to the permanent magnet and the control magnetic flux generated by the electromagnets increases and decreases the bias magnetic flux generated by the permanent magnet 11.

If the control magnetic flux is generated in a clockwise direction, the control magnetic flux increases the intensity of magnetic field at the right gap while decreasing the intensity of magnetic field at the left gap, thereby moving the floating body to the right.

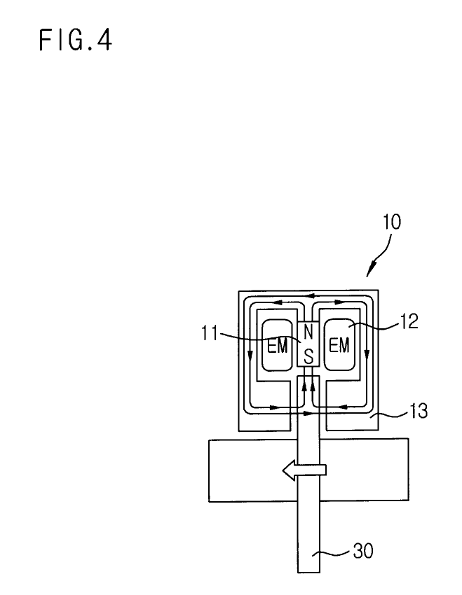

On the other hand, if the floating body 30 is moved to the right, the direction and amount of current applied to the electromagnets 12 is controlled to allow the electromagnets 12 to generate a control magnetic flux in a counterclockwise direction, thereby moving the floating body 30 to the left, as shown in FIG. 4.

That is, if the control magnetic flux generated by the electromagnets 12 is in a counterclockwise direction, the control magnetic flux decreases the intensity of magnetic field at the right gap while increasing the intensity of magnetic field at the left gap, thereby moving the floating body to the left.

While the conventional magnetic bearing requires two pairs of current drive circuits since it is implemented to be differential, the magnetic bearing using the bias magnetic flux of the permanent magnet according to the invention has an advantage in that it can operate with one current drive circuit since the same current flows through the coils.

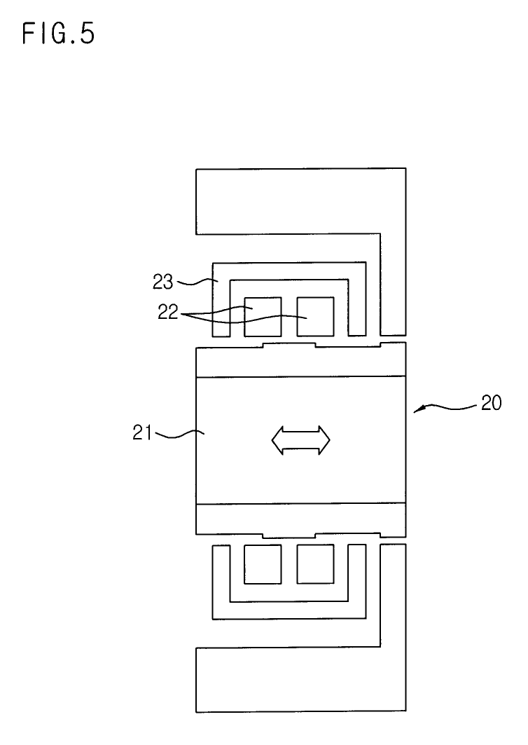

The thrust displacement sensor 20 for detecting changes in the position of the floating body 30 includes a shaft 21 having different diameters, a pair of ring electrodes 22 provided outside the shaft 21, and a guard electrode 23 surrounding the pair of ring electrodes 22 as shown in FIG. 5. The thrust displacement sensor 20 detects changes in the capacitance formed by the ring electrodes 22 by amplifying the capacitance changes using a differential amplifier.

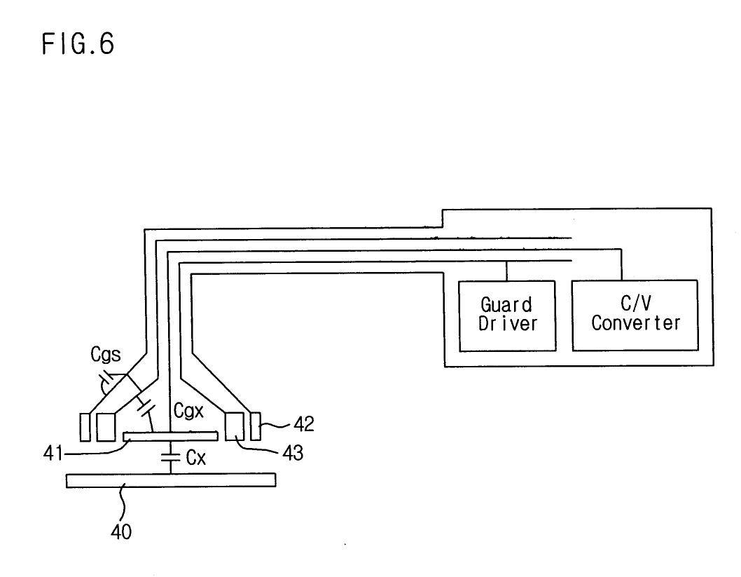

As shown in FIG. 6, the thrust displacement sensor 20 guards signals of a guard electrode 43 by covering the guard electrode 43 with a ground electrode 42 in order to minimize a parasitic capacitance formed between a sensor 41 and ground, other than the capacitance between the sensor 41 and a measurement target 40.

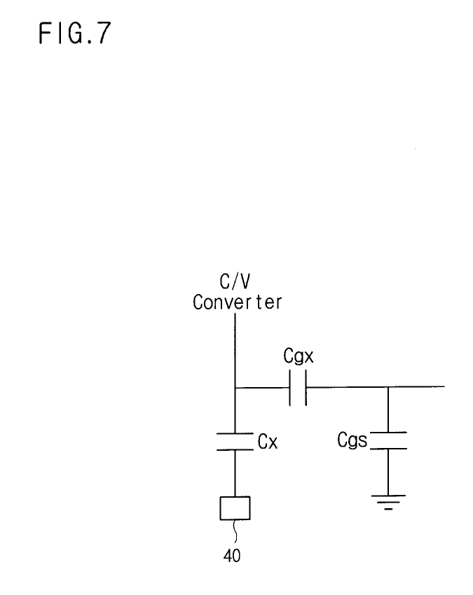

FIG. 7 illustrates a circuit equivalent to the thrust displacement sensor 20 of FIG. 6, where “Cx” represents a capacitance between the sensor 41 and the measurement target 40, “Cgx” represents a capacitance between the sensor 41 and the guard electrode 43, and “Cgs” represents a capacitance between the guard electrode 43 and the ground electrode 42.

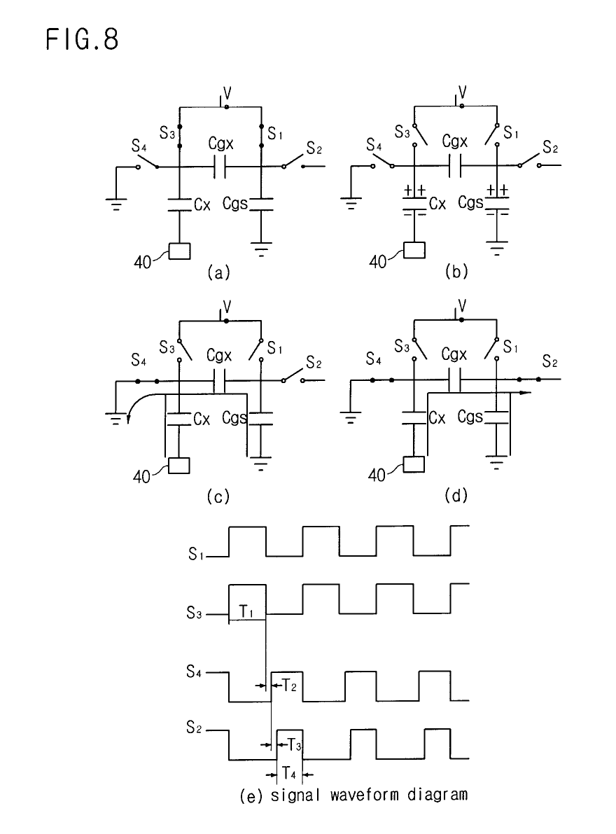

A switch circuit as shown in FIGS. 8A to 8D, which is used with a switch guard method, is constructed in order to exclude parasitic capacitances from the thrust displacement sensor constructed as described above in the capacitance detection method. A charge transfer method is applied to the switch circuit in order to exclude the parasitic capacitances. In the charge transfer method, an unknown capacitance is charged to a specific voltage and charges stored on the unknown capacitance are then discharged to produce an instantaneous current, which is then integrated through an amplifier to obtain a DC voltage proportional to the unknown capacitance.

The following is a more detailed description with reference to FIGS. 8A to 8E. First, as shown in FIG. 8A, switches S1 and S3 are closed while switches S2 and S4 are opened during a time interval T1 to charge both an unknown capacitance (or capacitor) Cx formed by a sensor and a measurement target and a capacitance Cgs formed by a guard electrode and ground to a specific voltage Vc and to discharge a capacitance Cgx formed by the sensor and the guard electrode.

Then, the switches S1 and S3 are opened simultaneously as shown in FIG. 8B. Then, the switch S4 is closed after the switches S2 and S4 are kept opened during a time interval T2 as shown in FIG. 8C. As the switch S4 is closed, charges stored on the unknown capacitance Cx are partially transferred to the empty capacitance Cgx between the sensor and the guard electrode and all charges stored on the capacitance Cgs are discharged.

Then, as shown in FIG. 8D, the switch S2 is closed after a small time interval T3 so that all the charges originally stored on the sensor are transferred to an OP amp, which is a charge detector circuit, during a time interval T4. As a result, it is possible to minimize the influence of the unnecessary capacitances Cgs and Cgx, other than the unknown capacitance Cx.

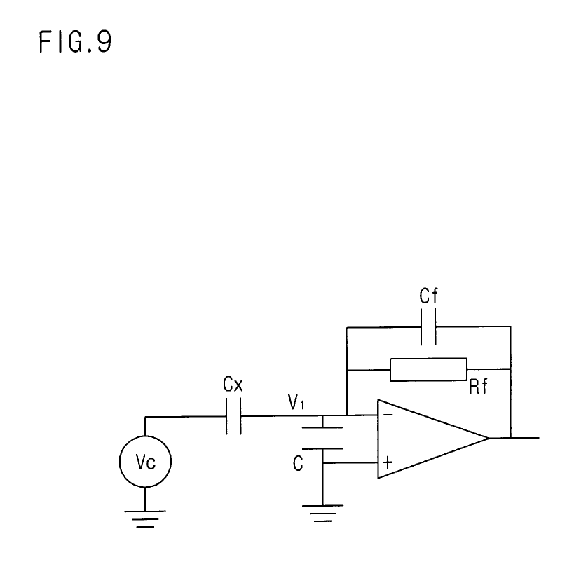

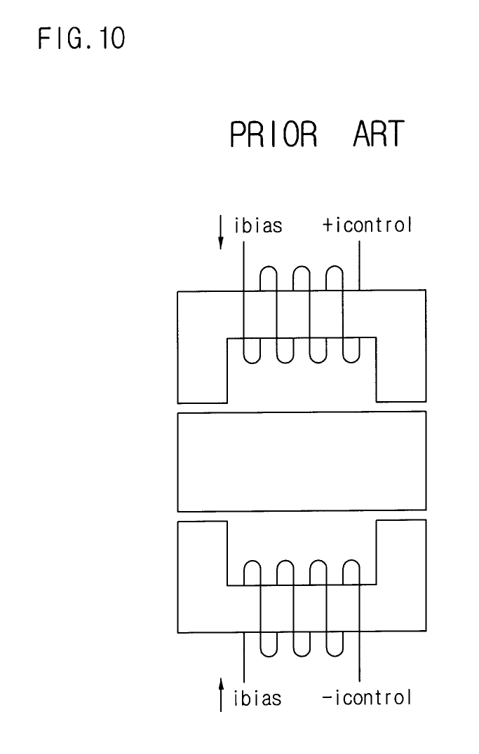

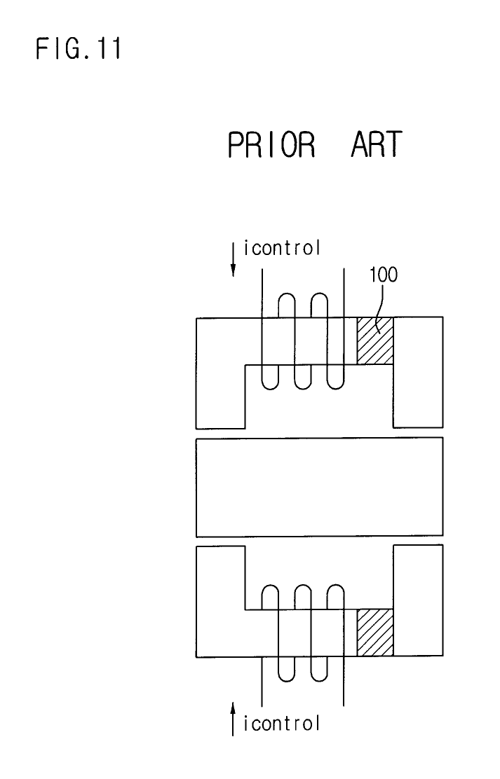

A current integration circuit, which includes an OP amp, a feedback resistor Rf, and a feedback capacitor Cf as shown in FIG. 9, is used as a basic circuit constructed to use the charge transfer method. Here, a DC output voltage proportional to the unknown capacitance Cx can be obtained by integrating a discharge current pulse with a very large integration constant Tf=RfCf selected to minimize the influence of the switching frequency f.

Since the input impedance of the OP amp varies depending on circumstances, a discharge current may flow into an input of the OP amp, causing an abrupt voltage increase. To prevent this, it is preferable that a capacitor C with a capacitance much higher than the unknown capacitance Cx be provided between the input of the OP amp and ground to absorb the instantaneous current, thereby keeping the input grounded.

As is apparent from the above description, the present invention provides a thrust magnetic bearing system with a variety of advantages. For example, magnetic circuits of electromagnets are separated from those of permanent magnets in the thrust magnetic bearing system so that each permanent magnet produces a basic magnetic field while each electromagnet functions only to control a magnetic force to control the position of a rotating body. This makes it possible to control the displacement of the rotating body while achieving displacement and current stiffness levels similar to those of the electromagnet type magnetic bearing without flowing a bias current through the electromagnet.

In addition, while the conventional magnetic bearing requires two pairs of current drive circuits since it is implemented to be differential, the magnetic bearing using the bias magnetic flux of the permanent magnet according to the invention can operate with one current drive circuit since the same current flows through coils.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A thrust magnetic bearing system including a thrust displacement sensor and a thrust magnetic bearing, the system floating a disk floating body based on displacement information detected through the thrust displacement sensor,
the thrust magnetic bearing including:
a donut permanent magnet;
a pair of electromagnets connected in series to form an inductor at both sides of the donut permanent magnet; and
a pair of magnetic poles provided opposite each other outside the pair of electromagnets,
wherein the thrust magnetic bearing floats the disk floating body through a bias magnetic flux generated by the donut permanent magnet and a control magnetic flux generated by the electromagnets.

2. The thrust magnetic bearing system according to claim 1, wherein the thrust displacement sensor includes:
a shaft having different diameters;
a pair of ring electrodes provided outside the shaft; and
a guard electrode surrounding the pair of ring electrodes,
wherein the thrust displacement sensor detects changes in a capacitance formed by the ring electrodes by amplifying the capacitance changes using a differential amplifier.
